(19) United States
(12) Patent Application Publication
(10) Pub. No.: US 2020/0083128 A1
(43) Pub. Date: Mar. 12, 2020

(54) FLEXIBLE PACKAGE

(71) Applicant: Samsung Electronics Co., Ltd., Suwon-si (KR)

(72) Inventor: Maohua Du, Suzhou City (CN)

(73) Assignee: Samsung Electronics Co., Ltd., Suwon-si (KR)

(21) Appl. No.: 16/407,618

(22) Filed: May 9, 2019

(30) Foreign Application Priority Data
Sep. 12, 2018 (CN) 201811060732.4

(51) Int. Cl. H01L 23/18; H01L 23/31; H01L 23/00; H01L 23/498; H01L 23/29

(52) U.S. Cl. CPC H01L 23/18; H01L 23/3128; H01L 24/48; H01L 23/4985; H01L 2224/32225; H01L 2224/48225; H01L 24/16; H01L 2224/16225; H01L 24/32; H01L 23/295

(57) ABSTRACT

The present disclosure provides a flexible package including: a flexible substrate; at least one chip attached on an upper surface of the flexible substrate; a conductive member electrically connecting the at least one chip and the flexible substrate; a relief layer covering a side surface of the at least one chip; and a flexible encapsulant encapsulating the flexible substrate and the at least one chip, wherein an elongation of the relief layer is greater than that of the flexible encapsulant. The flexible package according to an example embodiment of the present disclosure has improved deformability and/or may prevent breakage when the flexible package is bent.

### CROSS-REFERENCE TO RELATED APPLICATION

This application claims the benefit of Chinese Patent Application No. 201811060732.4, filed on Sep. 12, 2018, in the National Intellectual Property Administration of China, the disclosure of which is incorporated herein in its entirety by reference.

### BACKGROUND

### 1. Field

The present disclosure is suitable for a semiconductor packaging field, in particular, relates to a flexible package.

### 2. Description of the Related Art

A wearable electronic device is an electronic device that is worn on, for example, a human body (e.g. a wrist, neck, head, etc.), and are currently in widespread use. Since the skin of the human body has a certain contour rather than being flat, the wearable electronic device having a rigid package is not suitable for wearing on the human body.

In the existing flexible packaging technology, the flexible package is made to reach a bendable effect by using an encapsulant (which is generally a molding compound such as an epoxy molding compound (EMC)) with a high elongation, but since a chip is a rigid body, a connecting/contact region between the chip and the molding compound sealing the chip forms a deformation concentration region, which is easy to break when being bent. If the elongation of the molding compound is greatly increased, a coefficient of thermal expansion (CTE) of the molding compound may be increased, thereby reducing the reliability of the package.

### SUMMARY

Example embodiments provide a flexible package having improved or excellent bending properties without reducing chip protection performance.

According to one aspect, an example embodiment provides a flexible package including: a flexible substrate; at least one chip on an upper surface of the flexible substrate; a conductive member electrically connecting the at least one chip and the flexible substrate; a relief layer covering a side surface of the at least one chip; and a flexible encapsulant encapsulating the flexible substrate and the at least one chip, wherein an elongation of the relief layer is greater than that of the flexible encapsulant.

According to an example embodiment, the elongation of the relief layer may be greater than 100%.

According to an example embodiment, the relief layer may cover a side surface of each of the at least one chip.

According to an example embodiment, the relief layer may completely cover all side surfaces of each chip, and a height of the relief layer is the same as that of each chip.

According to an example embodiment, the relief layer has a thickness of less than 300 μm in a direction parallel to an extending direction of the flexible substrate.

According to an example embodiment, a material of the relief layer may be silica gel.

According to an example embodiment, the flexible encapsulant may be above and below the flexible substrate.

According to an example embodiment, a material of the flexible encapsulant may be an epoxy molding compound, and the content of silicon dioxide is less than 50 part by weight in the epoxy molding compound, and the epoxy molding compound has an elastic modulus of less than 2 GPa and the elongation of more than 10%.

According to an example embodiment, each of the at least one chip may has a thickness of less than 200 μm, and an area of each chip may be less than 50% of an area of the flexible package.

According to an example embodiment, the flexible package may be bendable.

According to an example embodiment, the material of the flexible substrate may be PI, PET, PEN, PEEK, or a prepreg.

According to an example embodiment, the conductive member may be a bonding wire, a bump, or a conductive paste.

The flexible package according to an example embodiment may have improved deformability and/or reliability, and/or may reduce or prevent breakage when the flexible package is bent.

### BRIEF DESCRIPTION OF THE DRAWINGS

The other features of example embodiments will become more apparent by following detailed description taken in connection with example embodiments with reference to the accompanying drawings, in which:

FIG. 1 is a cross-sectional view showing a flexible package in the prior art;

FIG. 2 is a diagram showing a stress distribution of the flexible package in the prior art;

FIG. 3 is a sectional view showing the occurrence of the breakage in the flexible package in the prior art;

FIG. 4 is a cross-sectional view showing a flexible package according to an example embodiment; and

FIG. 5 is a cross-sectional view showing a flexible package according to another example embodiment.

### DETAILED DESCRIPTION OF EXAMPLE EMBODIMENTS

Hereinafter, embodiments will be described in detail with reference to the accompanying drawings.

In the drawings, the thickness of layers, films, panels, regions, etc., may be exaggerated for clarity Like reference numerals designate like elements throughout the specification. It will be understood that when an element such as a layer, film, region, or substrate is referred to as being “on” another element, it may be directly on the other element or intervening elements may also be present. Alternatively, when an element is referred to as being “directly on” another element, there are no intervening elements.

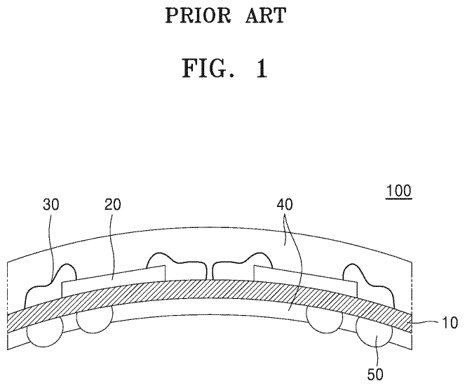

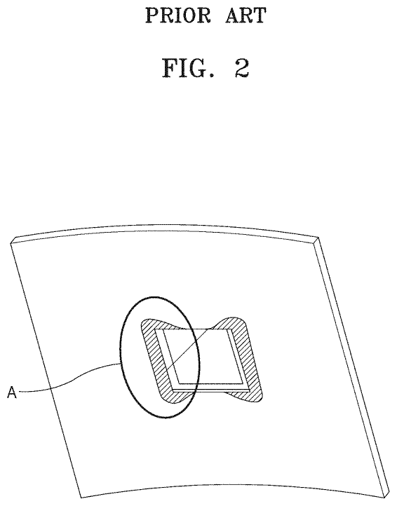

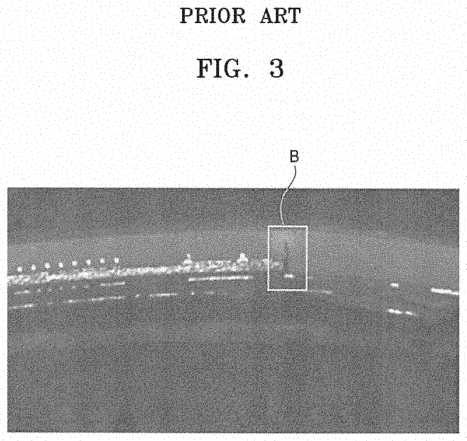

FIG. 1 is a cross-sectional view showing a flexible package 100 in the prior art. FIG. 2 is a diagram showing a stress distribution of the flexible package 100 in the prior art. FIG. 3 is a sectional view showing breakage in the flexible package 100 in the prior art.

In the flexible package 100 of the prior art, as shown in FIG. 1, a chip 20 is fixed on a substrate 10, and is connected with the substrate 10 through a conductive member 30 (for example, a bonding wire), the chip 20 is protected by an encapsulant 40, and the encapsulant 40 is generally a molding compound and has a characteristics of a low modulus and a high ductility. When being bent, the encapsulant 40 is easily bent due to having the high ductility, but the chip 20 is difficult to deform due to being a rigid body, and thus a stress concentration region is formed at a contact/connecting area between the chip 20 and the encapsulant 40, as shown in an “A” region in FIG. 2; when being subjected to excessive bending, a lacerated wound may occur at the contact/connecting area between the chip 20 and the encapsulant 40, as shown in a “B” region in FIG. 3, which finally results in an overall breakage of the flexible package 100.

Therefore, a problem to be faced in the prior art is that: it is desired to increase the elongation of the molding compound, so that the molding compound may be resistant to higher deformation and it is possible to improve a bending ability of the package, however, excessively increasing the elongation of the molding compound may result in reducing the modulus of the molding compound and excessively high CTE, and result in the chip protection insufficient and thermal matching failure due to excessive CTE, which forms a technical contradiction.

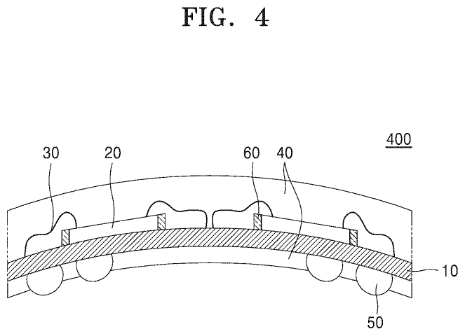

FIG. 4 is a cross-sectional view showing a flexible package 400 according to an example embodiment.

The flexible package 400 according to an example embodiment may include a substrate 10, chips 20, a conductive member 30, an encapsulant 40, solder balls 50 and a relief layer 60. The flexible package 400 can be used in any wearable electronic device, for example, a wrist-worn electronic device such as a smart watch or a bracelet, a necklace-type electronic device, a glasses-type electronic device, and the like.

Referring to FIG. 4, in the flexible package 400 according to an example embodiment, at least one chip 20 may be attached to an upper surface of the substrate 10, the conductive member 30 may connect the at least one chip 20 and the substrate 10, the relief layer 60 may cover a side surface of the at least one chip 20, and the encapsulant 40 may be disposed above and below the substrate 10 and encapsulate the substrate 10 and the at least one chip 20, wherein the elongation of the relief layer 60 may be greater than the elongation of the encapsulant 40, and the elongation of the relief layer 60 can be greater than 100%.

Respective components in the flexible package 400 according to an example embodiment will be described in detail below.

In an example embodiment, the relief layer 60 may cover or surround at least one side surface of the at least one chip 20, for example, completely cover all side surfaces of each chip 20. Alternatively, the relief layer 60 is not provided on the upper or lower surface of each chip 20, but is not limited thereto. A height of the relief layer 60 may be the same as a height of each chip 20 in a vertical direction perpendicular to the substrate 10. The relief layer 60 may have a thickness of less than 300 μm in a direction parallel to an extending direction of the substrate 10. The elongation of the relief layer 60 may be greater than that of the encapsulant 40, and preferably, the elongation of the relief layer 60 is greater than 100%. For example, the material of the relief layer 60 may be silica gel, but is not limited thereto. Alternatively, the material of the relief layer 60 may be other materials having a higher elongation.

Therefore, the relief layer 60 with an ultra-high elongation may be covered around each chip 20 (for example, side surfaces of each chip 20), that is, the relief layer 60 may be disposed between each chip 20 and the encapsulant 40, thereby when the flexible package 400 is highly bent and deformed, the relief layer 60 may bear a high strain due to its ultra-high elongation (for example, >100%), and the occurrence of the breakage between the chips 20 and the encapsulant 40 may be reduced or prevented.

The substrate 10 may generally be a flexible substrate, for example, the material of the substrate 10 may be PI, PEN, PEEK, PET or prepreg, but example embodiments are not limited thereto. The substrate 10 may have a thickness of less than 200 μm to ensure flexibility and/or a good curved surface fitting/bonding performance of the flexible package 400.

At least one chip 20 may be attached to the upper surface of the substrate 10, and a surface of each chip 20 may have pads (not shown). As shown in FIG. 4, the chip 20 can be electrically connected to the substrate 10 by the pads on the chip and the conductive member 30 (e.g., the bonding wire). When the number of the chips 20 is plural, a plurality of chips 20 may have the same size or different sizes. Each chip 20 may have a thickness of less than 200 μm. On a plane (e.g., a horizontal plane) parallel to a plane in which the substrate 10 extends, an area of each chip 20 may be less than 50% of an area of the flexible package 400, so as to achieve the good fitting/bonding of the chips 20 and the substrate 10 in the bending process of the flexible package 400, thereby the bending of the flexible package 400 is better achieved. Alternatively, the area of each chip 20 may be less than 50% of the area of the substrate 10.

The conductive member 30 may be a bonding wire, a bump or a conductive paste. As shown in FIG. 4, when the conductive member 30 is a bonding wire having a curved shape with a concave portion and a convex portion, the conductive member 30 having the curved shape may not be broken due to excessively elongated when the flexible package 400 is bent inwardly or outwardly, thereby improving the reliability of the flexible package 400. In another example embodiment, the conductive member 30 may be bumps (not shown) such as solder balls or protrusions, each chip 20 may be connected to the substrate 10 in a flip-chip way by the pads on the chips and the conductive member 30 such as the solder balls or the bumps. In another example embodiment, the conductive member 30 electrically connects each chip 20 and the substrate 10 in a form of the conductive paste.

The encapsulant 40 may be disposed above and below the substrate 10 and encapsulate the substrate 10 and the at least one chip 20, for example, the encapsulant 40 may be disposed on an upper surface of the substrate 10 and may also be disposed on a lower surface of the substrate 10. That is, the encapsulant 40 may be disposed on the upper and lower sides of the substrate 10 to encapsulate and protect the substrate 10, the chips 20, the conductive members 30 and the relief layer 60, and to reduce the risk of damage of the chip 20. The encapsulant 40 may be disposed on the upper and lower sides of the substrate 10 to achieve a stress balance, thereby reducing or minimizing internal stress caused by thermal expansion coefficient mismatch, so as to ensure the flexibility of the flexible package 400. In example embodiments, the encapsulant 40 may encapsulate the substrate 10 on the upper and lower sides of the substrate, but the left and right sides of the substrate 10 are exposed. Alternatively, the encapsulant 40 may completely seal the substrate 10, that is, seal the upper and lower sides and the left and right sides of the substrate 10.

Generally, the encapsulant 40 may be a flexible encapsulant. The material of the flexible encapsulant may be the molding compound such as the epoxy molding compound (EMC). In example embodiments, the content of silica is less than 50 part by weight in the epoxy molding compound, and the epoxy molding compound has an elastic modulus of less than 2 GPa and an elongation of more than 10%. In addition, the encapsulant 40 may block external moisture and/or air, and protect the chips 20 from the external environment.

A plurality of solder balls 50 may be disposed on the lower surface of the substrate 10 and connected to the substrate 10 by penetrating through the flexible encapsulant 40, thereby a connection with an external device may be achieved.

In an example embodiment, the flexible package 400 is bendable. In particular, the flexible package 400 may be bent outwardly (e.g., downwardly) to have a convex shape as shown in FIG. 4.

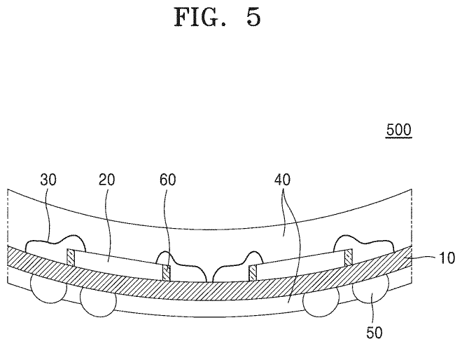

FIG. 5 is a cross-sectional view showing a flexible package 500 according to another example embodiment. In FIG. 5, the flexible package 500 can be bent inwardly (e.g., upwardly) to have a concave shape. The flexible package 500 in FIG. 5 has the same elements as those of the flexible package 400 in FIG. 4, except that it is different from the bent shape of the flexible package 400 in FIG. 4, and a repetitive description will not be made herein.

As shown in FIGS. 4 and 5, the flexible package 400 or 500 may be bent outwardly to have the convex shape or bent inwardly to have a concave shape. When the flexible package 400 or 500 is in a bent state, the surface of each chip 20 may not be in a horizontal plane. The flexible package 400 or 500 having the flexible substrate 10 and the flexible encapsulant 40 according to an example embodiment may be bent and deformed as needed, and may have improved curved surface fitting/bonding performance without the breakage of the flexible package 400 or 500.

A method of manufacturing the flexible package 400 or 500 shown in FIG. 4 or FIG. 5 according to an example embodiment may include: preparing a substrate 10; attaching at least one chip 20 to an upper surface of the substrate 10 at a predetermined or desired interval; after the attaching is completed, a buffer material (for example, silica gel) is coated on the periphery (e.g., all side surfaces) of each chip 20 by dispensing, so that the coated buffer material has the same height as that of each chip 20 and has a thickness of less than 300 μm; curing the buffer material by a way of heating or ultraviolet curing, thereby forming a relief layer 60; connecting each chip 20 to the substrate 10 by a conductive member (for example, a bonding wire) 30; and disposing the encapsulant 40 above and below the substrate 10, and making the encapsulant 40 to encapsulate the substrate 10, the chip 20, and the conductive member 30. Thereafter, by adopting a bending process or technique commonly used in the art, the flexible package may be bent outwardly to form the flexible package 400 as shown in FIG. 4; alternatively, the flexible package can be bent inwardly to form the flexible package 500 as shown in FIG. 5. In another example embodiment, the flexible package may be a flexible package that may be deformed according to the skin or wearing position of the human body, and is not limited to the bent shape and radian shown in FIG. 4 or FIG. 5.

In an example embodiment, referring to FIGS. 4 and 5, by using the substrate 10 having flexibility, the encapsulant (e.g., EMC) 40 having flexibility, and the relief layer (e.g., silica gel) 60 having an ultra-high elongation disposed between the at least one chip 20 and the encapsulant 40, the flexible package 400 or 500 having improved or excellent bending properties may be formed. Alternatively, the encapsulants 40 may be disposed on the upper and lower sides of the substrate 10 to achieve the stress balance, thereby reducing or minimizing internal stress caused by thermal expansion coefficient mismatch, so as to ensure the flexibility of the flexible package 400 or 500. In addition, in example embodiments, the encapsulant 40 may be an epoxy molding compound having flexibility, and the content of silica is less than 50 part by weight in the epoxy molding compound, and the epoxy molding compound has the elastic modulus of less than 2 GPa and the elongation of greater than 10%. In addition, the elongation of the relief layer 60 may be greater than 100% and greater than that of the encapsulant 40, thereby forming a transition region at the contact/connecting area between the chip 20 and the encapsulant 40 by the relief layer 60 having the ultra-high elongation, and reducing or preventing breakage of the package 400 or 500 and/or improving the deformability of the flexible package 400 or 500.

While one or more example embodiments have been described with reference to the drawings, it will be understood by those of ordinary skill in the art that various changes in form and details may be made therein without departing from the spirit and scope defined by the claims.

What is claimed is:

1. A flexible package, comprising:
a flexible substrate;
at least one chip on an upper surface of the flexible substrate;
a conductive member electrically connecting the at least one chip and the flexible substrate;
a relief layer covering a side surface of the at least one chip; and
a flexible encapsulant encapsulating the flexible substrate and the at least one chip,
wherein an elongation of the relief layer is greater than that of the flexible encapsulant.

2. The flexible package of claim 1, wherein the elongation of the relief layer is greater than 100%.

3. The flexible package of claim 1, wherein the relief layer covers a side surface of each of the at least one chip.

4. The flexible package of claim 3, wherein the relief layer completely covers all side surfaces of each of the at least one chips, and a height of the relief layer is the same as that of each chip.

5. The flexible package according to claim 1, wherein the relief layer has a thickness of less than 300 μm in a direction parallel to an extending direction of the flexible substrate.

6. The flexible package of claim 1, wherein a material of the relief layer is silica gel.

7. The flexible package of claim 1, wherein the flexible encapsulant is above and below the flexible substrate.

8. The flexible package of claim 1, wherein a material of the flexible encapsulant is an epoxy molding compound, and the content of silica is less than 50 part by weight in the epoxy molding compound, and the epoxy molding compound has an elastic modulus of less than 2 GPa and an elongation of more than 10%.

9. The flexible package of claim 1, each of the at least one chips has a thickness of less than 200 μm, and an area of each of the at least one chips is less than 50% of an area of the flexible package.

10. The flexible package of claim 1, wherein the flexible package is bendable.
